(19) United States
(12) Patent Application Publication
(10) Pub. No.: US 2026/0173407 A1
(43) Pub. Date: Jun. 18, 2026

(54) SEMICONDUCTOR DEVICE AND METHOD OF MANUFACTURING SEMICONDUCTOR DEVICE

(71) Applicant: Kioxia Corporation, Tokyo (JP)

(72) Inventor: Kazuma HASEGAWA, Fujisawa Kanagawa (JP)

(21) Appl. No.: 19/309,581

(22) Filed: Aug. 25, 2025

(30) Foreign Application Priority Data
Dec. 17, 2024 (JP) 2024-220453

(51) Int. Cl. H10B 80/00; H01L 25/00; H01L 25/065; H01L 25/11; H01L 25/18

(52) U.S. Cl. CPC H10B 80/00; H10W 90/00; H10W 90/24; H10W 90/291; H10W 90/722; H10W 90/752; H10W 90/754

(57) ABSTRACT

According to one embodiment, a semiconductor device includes a first semiconductor chip on a substrate and a sealing material covering the first semiconductor chip. The sealing material includes a plurality of fillers and has a first surface. The first semiconductor chip is between the first surface and the substrate. A first conductive structure in the device has a first end portion electrically connected to the first semiconductor chip. The first conductive structure extends to the first surface through the sealing material and has a second end portion at the first surface. A second conductive structure of the device is connected to the second end portion and extends along the first surface. The plurality of fillers is only present in the sealing material at a depth position below the first surface.

### CROSS-REFERENCE TO RELATED APPLICATION

This application is based upon and claims the benefit of priority from Japanese Patent Application No. 2024-220453, filed Dec. 17, 2024, the entire contents of which are incorporated herein by reference.

### FIELD

Embodiments described herein relate generally to a semiconductor device and a method of manufacturing a semiconductor device.

### BACKGROUND

A semiconductor package in which a semiconductor chip is sealed by a sealing material is disclosed. In order to provide electrical lead outs from the semiconductor chip, a conductive layer extending from the semiconductor chip may be exposed from the sealing material for forming a wiring layer on the exposed surface. In this case, when this exposed surface is uneven, it is difficult to form the wiring layer.

### BRIEF DESCRIPTION OF THE DRAWINGS

FIGS. 1A and 1B are diagrams illustrating an example of a configuration of a semiconductor device according to a first embodiment.

FIGS. 2A to 2C are cross-sectional views sequentially illustrating a part of a procedure of a method of manufacturing the semiconductor device according to the first embodiment.

FIGS. 3A and 3B are cross-sectional views sequentially illustrating a part of the procedure of the method of manufacturing the semiconductor device according to the first embodiment.

FIGS. 4A to 4D are cross-sectional views sequentially illustrating a part of the procedure of the method of manufacturing the semiconductor device according to the first embodiment.

FIGS. 5A and 5B are cross-sectional views sequentially illustrating a part of the procedure of the method of manufacturing the semiconductor device according to the first embodiment.

FIGS. 6A and 6B are cross-sectional views illustrating a part of a procedure of a method of manufacturing a semiconductor device according to Comparative Example.

FIGS. 7A and 7B are cross-sectional views illustrating a part of a procedure of a method of manufacturing a semiconductor device according to a first modification example of the first embodiment.

FIGS. 8A and 8B are cross-sectional views illustrating a part of a procedure of a method of manufacturing a semiconductor device according to a second modification example of the first embodiment.

FIGS. 9A and 9B are cross-sectional views illustrating a part of the procedure of the method of manufacturing the semiconductor device according to the second modification example of the first embodiment.

FIGS. 10A to 10C are cross-sectional views illustrating a part of a procedure of a method of manufacturing a semiconductor device according to a third modification example of the first embodiment.

FIGS. 11A to 11C are cross-sectional views illustrating a part of a procedure of a method of manufacturing a semiconductor device according to a fourth modification example of the first embodiment.

FIG. 12A is a diagram illustrating an example of a configuration of a semiconductor device according to a second embodiment.

FIG. 12B is a diagram illustrating another example of the configuration of the semiconductor device according to the second embodiment.

FIG. 13 is a diagram illustrating an example of a configuration of a semiconductor device according to a third embodiment.

FIG. 14 is a diagram illustrating another example of the configuration of the semiconductor device according to the third embodiment.

FIG. 15 is a diagram illustrating an example of a configuration of a semiconductor device according to Comparative Example.

### DETAILED DESCRIPTION

Embodiments provide a semiconductor device where a wiring layer can be easily formed on a sealing member and a method of manufacturing such a semiconductor device.

In general, according to one embodiment, a semiconductor device includes a first semiconductor chip on a substrate and a sealing member covering the first semiconductor chip. The sealing member includes a plurality of fillers and has a first surface. The first semiconductor chip is between the first surface and the substrate. A first conductive structure of the device has a first end portion electrically connected to the first semiconductor chip. The first conductive structure extends to the first surface through the sealing member and has a second end portion at the first surface. A second conductive structure of the device is connected to the second end portion and extends along the first surface. The plurality of fillers is only present in the sealing member at a depth position below the first surface.

Hereinafter, certain example embodiments will be described with reference to the drawings. The present disclosure is not limited to the following example embodiments. In addition, components in the following embodiments include those that are easily conceivable by persons skilled in the art or substantial equivalents thereof.

### First Embodiment

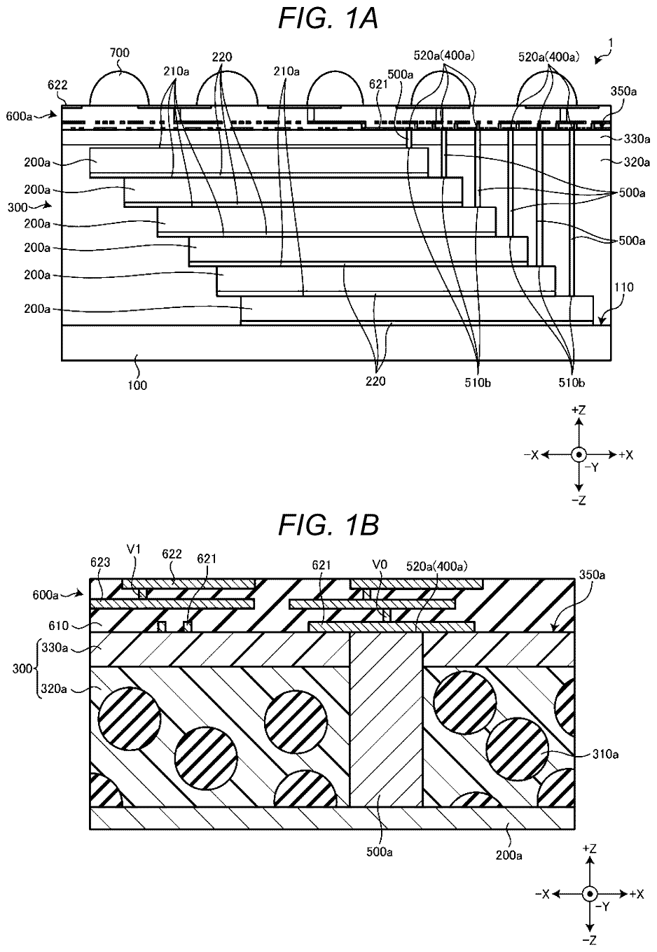

Hereinafter, a first embodiment will be described with reference to FIGS. 1A to 5B.

### Configuration Example of Semiconductor Device

FIGS. 1A and 1B are diagrams illustrating an example of a configuration of a semiconductor device according to the first embodiment. Specifically, FIG. 1A is a cross-sectional view taken along an X direction of a semiconductor device 1, and FIG. 1B is an enlarged cross-sectional view including a surface 350a of a sealing member 300. It should be noted that FIG. 1A does not include hatching in consideration of easier understanding of the drawing.

As illustrated in FIG. 1A, the semiconductor device 1 is configured as a package in which a plurality of semiconductor chips 200a are sealed (enclosed/encapsulated). Specifically, the semiconductor device 1 includes a support 100, a plurality of semiconductor chips 200a, a sealing member 300, an electrode 400a, a vertical wire 500a, a redistribution layer 600a, and a solder ball 700.

In the present embodiment, it is assumed that the side of the support 100 of the semiconductor device 1 can be referred to as a lower side, the side of the solder ball 700 of the semiconductor device 1 can be referred to as an upper side, and this up-down direction is a Z direction. In addition, a direction from the lower side toward the upper side of the semiconductor device 1 will be also referred to as a stacking direction of the semiconductor chips 200a. The X direction and the Y direction are directions along (parallel to) a surface of the semiconductor chip 200a, and the X direction and the Y direction are perpendicular to each other. In addition, it is assumed that for the X-axis, the Y-axis, and the Z-axis, the direction indicated by an arrow is a positive direction and the direction opposite to the arrow is a negative direction.

The support 100 is, for example, a lead frame, which can be a metal sheet comprising a metal such as iron (Fe), copper (Cu), nickel (Ni), or magnesium (Mg) or an alloy or the like including at least one of the metals. The plurality of semiconductor chips 200a are stacked on an upper surface 110 of the support 100.

The support 100 is not limited to the above and, in general, any material or substrate type may be adopted as long as it can function as a supporting substrate when the semiconductor chips 200a are being stacked or thereafter. For example, a flat plate-shaped member such as a silicon (Si) substrate, a glass substrate, or a stainless steel plate may be adopted.

Each of the semiconductor chips 200a is a smaller piece diced from a larger silicon (Si) wafer or the like, and includes, for example, a semiconductor element on a main surface 210a side. In some examples, the semiconductor element may be a nonvolatile memory such as a NAND flash memory. The semiconductor chip 200a is an example of a first semiconductor chip.

A plurality of semiconductor chips 200a does not necessarily need to be stacked on the upper surface 110 of the support 100, and a single semiconductor chip 200a may be disposed thereon.

In the present example, a plurality of semiconductor chips 200a are sequentially stacked while being shifted in the negative X direction with the main surfaces 210a directed upward. As a result, an end portion of the main surface 210a of each of the semiconductor chips 200a on the side in positive X direction is not overlapped by the semiconductor chip 200a immediately above. In this portion of the semiconductor chip 200a (the end portion of the main surface 210a in the positive X direction), one or more electrode pads are provided at the uppermost layer. A vertical wire 500a can be connected to each electrode pad.

An adhesive layer 220 is provided on a surface of the semiconductor chip 200a opposite to the main surface 210a, that is, a lower surface. The adhesive layer 220 is, for example, a thermosetting resin such as a die attach film (DAF) that is formed in a film shape.

For example, the adhesive layer 220 provided on the lower surface of the semiconductor chip 200a at the lowermost layer bonds the upper surface 110 of the support 100 and the semiconductor chip 200a at the lowermost layer to each other. In addition, the adhesive layer 220 provided on the lower surface of the second semiconductor chip 200a from the lowermost layer bonds the semiconductor chip 200a at the lowermost layer and the second semiconductor chip 200a from the lowermost layer to each other. As a result, the support 100 and each of the plurality of semiconductor chips 200a are fixed to each other.

The sealing member 300 seals (encapsulates) the plurality of semiconductor chips 200a. The sealing member 300 is, for example, a thermosetting resin material such as an epoxy resin or an acrylic resin. In at least a part of the sealing member 300, a plurality of fillers 310a are distributed therein.

More specifically, as illustrated in FIG. 1B, the sealing member 300 has a two-layer structure including a first layer 320a including the fillers 310a and a second layer 330a not including the fillers 310a. The first layer 320a is disposed in the lower portion of the sealing member 300 and covers the upper surface 110 of the support 100, the semiconductor chips 200a, and a lower portion of the vertical wire 500a. The second layer 330a is disposed in the upper portion of the first layer 320a and covers an upper portion of the vertical wire 500a. The second layer 330a has a surface 350a on the side opposite to the side where the first layer 320a is disposed. The surface 350a is an example of the first surface.

The fillers 310a are, for example, a metal oxide, such as aluminum oxide or copper oxide, or a metal nitride, such as aluminum nitride. The fillers are metal-containing particles having high thermal conductivity. The sealing member 300 with the plurality of fillers 310a therein and has higher thermal conductivity than the sealing member 300 alone (that is, without fillers 310a). As a result, heat generated by an operation of each of the semiconductor chips 200a is more efficiently diffused through the sealing member 300 incorporating fillers 310a. As a result, a decrease in the operating speed of the semiconductor chip 200a, an operational failure thereof, or the like that might be caused by heat generation is avoided. In addition, the plurality of fillers 310a may have a function of adjusting the viscosity, hardness, volume, and the like of the sealing member 300. The diameter of the filler 310a may be about 20 μm or less.

As described above, the plurality of fillers 310a are selectively provided in the first layer 320a of the sealing member 300. That is, the plurality of fillers 310a are present at a depth position lower than the second layer 330a. In other words, all of the plurality of fillers 310a are present at a depth position lower than the surface 350a of the second layer 330a.

In the present embodiment, the first layer 320a and the second layer 330a are formed of a same resin material. It should be noted that the material for forming the first layer 320a and the second layer 330a is not limited to the above description, and as long as the plurality of semiconductor chips 200a can be appropriately sealed, the first layer 320a and the second layer 330a may be formed of different resin materials rather than the same.

In addition, the sealing member 300 does not necessarily need to have a two-layer structure including a first layer 320a and a second layer 330a. As long as a layer or layer portion not including the fillers 310a is disposed on the uppermost layer, other arrangements may be adopted. For example, if the second layer 330a is disposed as the uppermost layer, the total number of layers below the second layer 330a can be freely selected.

As described above, each vertical wire 500a is connected to an electrode pad of one of the semiconductor chips 200a, extends upward in the first layer 320a and the second layer 330a and is exposed at the surface 350a. As a result, the semiconductor chips 200a are electrically led out to the surface 350a through the vertical wires 500a. That is, an end portion 520a of a vertical wire 500a that is exposed to the surface 350a functions as the electrode 400a for electrically leading out a semiconductor chip 200a. The vertical wire 500a comprises, for example, a metal material such as any one of Au, Cu, Pd, Cu, or Ag or alloys thereof. The vertical wire 500a is an example of a first conductive structure. For example, the vertical wire 500a is a columnar type structure.

The redistribution layer (RDL) 600a is formed on the surface 350a. The redistribution layer 600a includes an insulating layer 610, wiring layers 621 to 623, and via layers V0 and V1. The wiring layers 621 to 623 are disposed at multiple height positions in the insulating layer 610 and have wiring patterns extending along an XY plane at the respective height positions. The via layers V0 and V1 connect the wiring layers 621 to 623 to each other in the Z direction. The insulating layer 610 includes a polyimide resin, an epoxy resin, or the like, and the wiring layers 621 to 623 and the via layers V0 and V1 include a metal material such as Cu.

Among the wiring layers 621 to 623, the wiring layer 621 extends on the surface 350a and is connected to the electrode 400a. The wiring layer 621 is an example of the second conductive structure. The wiring layer 622 extends on an upper surface 611 of the insulating layer 610 and is connected to a solder ball 700. In the insulating layer 610, the wiring layer 623 disposed between the wiring layers 621 and 622, the via layer V0 that connects the wiring layers 621 and 623 to each other, and the via layer V1 that connects the wiring layers 623 and 622 to each other are provided.

It should be noted that the number and disposition of the wiring layers 623 that connect the wiring layers 621 and 622 to each other, the via layers V0 and V1, and the like may be freely selected.

With the redistribution layer 600a configured as described above, a plurality of electrodes 400a disposed on the surface 350a of the second layer 330a that is the lower surface side of the redistribution layer 600a are further led out to an upper surface of the redistribution layer 600a. The disposition positions of the individual electrodes 400a on the surface 350a of the second layer 330a and the lead-out positions of the electrodes 400a on the upper surface of the redistribution layer 600a can be made different from each other. That is, the electrodes 400a on the surface 350a of the second layer 330a can be redistributed on the upper surface of the redistribution layer 600a.

A plurality of solder balls 700 are provided on the upper surface 611 of the insulating layer 610. The plurality of solder balls 700 are electrically connected to the wiring layer 622 where the individual electrodes 400a are redistributed. As a result, the plurality of semiconductor chips 200a and the plurality of solder balls 700 are electrically connected. By connecting the plurality of solder balls 700 to a motherboard (e.g., a printed circuit board), the semiconductor device 1 can be mounted on the motherboard.

### Method of Manufacturing Semiconductor Device

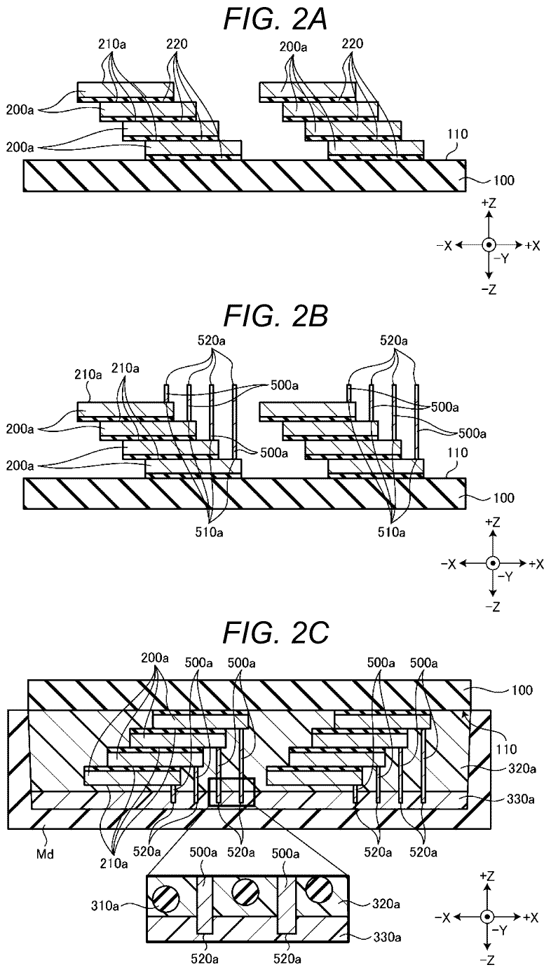

Next, a method of manufacturing the semiconductor device 1 according to the first embodiment will be described using FIGS. 2A to 5B. FIGS. 2A to 5B are cross-sectional views sequentially illustrating a part of a procedure of the method of manufacturing the semiconductor device according to the first embodiment.

As illustrated in FIG. 2A, the semiconductor chips 200a are sequentially stacked on the upper surface 110 of the support 100 while each in turn is shifted in the negative X direction. That is, the first semiconductor chip 200a is fixed to the upper surface 110 of the support 100 using the adhesive layer 220. In addition, the second, third, and so forth semiconductor chips 200a are sequentially fixed to the main surface 210a of the semiconductor chip 200a at the lower layer using the adhesive layer 220 while being offset in the negative X direction.

As illustrated in FIG. 2B, the vertical wire 500a extending in the stacking direction of the semiconductor chip 200a from an electrode pad on the main surface 210a of each of the semiconductor chips 200a is formed.

At this point, the vertical wire 500a reaches a position higher than the main surface 210a of the semiconductor chip 200a at the uppermost layer that is the uppermost surface. It is desirable that the height positions of the end portions 520a of the vertical wires 500a are substantially the same as each other.

Next, the plurality of semiconductor chips 200a and the vertical wires 500a (formed in FIG. 2B) are covered with the first layer 320a and the second layer 330a. Specifically, as illustrated in FIG. 2C, first, the non-cured second layer 330a is disposed on a bottom portion of a mold Md, and then the non-cured first layer 320a is disposed thereon. As described above, the first layer 320a includes the fillers 310a, the second layer 330a does not include the fillers 310a, and the first layer 320a and the second layer 330a are a thermosetting resin such as an epoxy resin or an acrylic resin. The first layer 320a and the second layer 330a can be formed of the same base resin material or different resin materials.

It can be preferable that the non-cured first layer 320a be fluid (flowable), while the non-cured second layer 330a be applied as a sheet or as a high viscosity material. For example, by reducing the amount of the solvent so the resin material is in the solvent at a high concentration, the viscosity of the second layer 330a increases, and the second layer 330a can be configured in a sheet shape. As a result, the non-cured first layer 320a and the non-cured second layer 330a can be prevented from being mixed while in the mold Md. As a result, the plurality of fillers 310a can be kept selectively present in the first layer 320a or substantially so.

It should be noted that, as long as the mixing with the first layer 320a can be avoided, the second layer 330a does not necessarily need to be applied as a sheet and, for example, may be applied as a fluid.

Next, the support 100 is inverted upside down such that the upper surface 110 of the support 100 is directed downward. As a result, the support 100 is disposed on the upper side, and the semiconductor chip 200a at the uppermost layer and the end portion 520a of the vertical wire 500a are disposed on the lower side. In this state, the entire support 100 is inserted into the mold Md up to a depth position where the end portion 520a of the vertical wire 500a reaches the second layer 330a disposed on the bottom portion of the mold Md.

At this time, the insertion depth of the support 100 is adjusted such that the semiconductor chip 200a of the uppermost layer, that is, the main surface 210a of the semiconductor chip 200a positioned on the lowermost side in FIG. 2C is positioned to be higher than the second layer 330a. At this time, the thicknesses of the first layer 320a and the second layer 330a in the mold Md may also be previously adjusted. As a result, subsequently, the first layer 320a covers the entirety of the semiconductor chips 200a.

In order to position the main surface 210a of the semiconductor chip 200a positioned on the lowermost side in FIG. 2C to be higher than the second layer 330a, the thicknesses of the first layer 320a and the second layer 330a in the mold Md may also be previously adjusted.

Next, the first layer 320a and the second layer 330a are heated and cured and are subsequently taken out from the mold Md.

As described above, the entirety of the semiconductor chips 200a including the vertical wires 500a is sealed within the sealing member 300 including the first layer 320a and the second layer 330a as covering. It should be noted that, at this stage, the surface 350a is not yet formed in the sealing member 300, and the end portion 520a of the vertical wire 500a is not exposed from the sealing member 300.

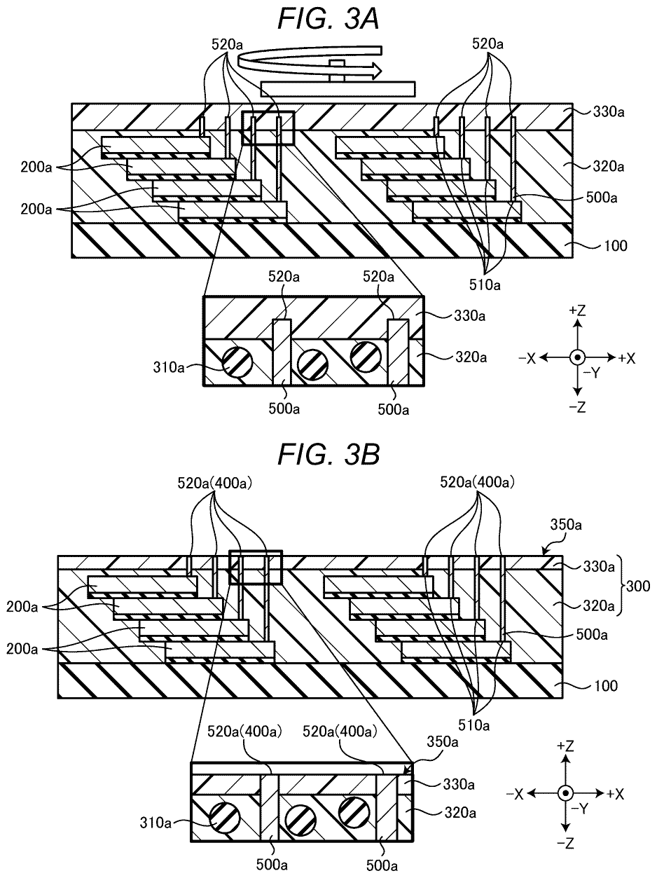

More specifically, as illustrated in FIG. 3A, in the sealing member 300, the first layer 320a surrounds a lower portion including the semiconductor chips 200a and end portions 510a of the vertical wires 500a, and the second layer 330a surrounds an upper portion including the end portions 520a of the vertical wires 500a.

Next, the second layer 330a is polished, for example, using a chemical mechanical polishing (CMP) method or the like to remove a portion thereof to reach a predetermined thickness. As a result, as illustrated in FIG. 3B, the height of the second layer 330a is reduced to form the surface 350a, and the end portion 520a of the vertical wire 500a is exposed at the surface 350a.

In this process, when the end portion 520a of the vertical wire 500a is exposed at the polishing surface while the portion of the second layer 330a is being removed, the exposed portion of the vertical wire 500a may also be polished (removed) along with the second layer 330a. By also polishing the exposed portion of the vertical wire 500a in this process, a height position of the surface 350a of the second layer 330a and a height position of the end portion 520a of the vertical wire 500a can be more precisely aligned.

As described above, the sealing member 300 including the surface 350a is formed. The end portion 520a of the vertical wire 500a exposed to the surface 350a of the sealing member 300 functions as the electrode 400a that electrically leads out the sealed semiconductor chips 200a.

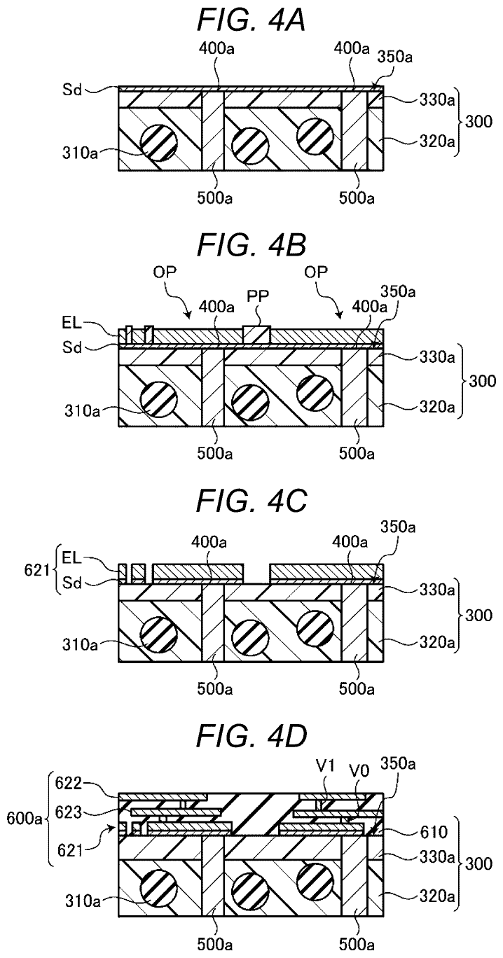

Next, a step of forming the redistribution layer 600a on the sealing member 300 will be described using FIGS. 4A to 4D. FIGS. 4A to 4D are enlarged cross-sectional views including the surface 350a of the sealing member 300.

As illustrated in FIG. 4A, a seed layer Sd that covers the surface 350a is formed using a sputtering method or the like. The seed layer Sd includes copper (Cu) or the like, and functions as a seed crystal when a plating layer EL is later formed on the surface 350a using an electroplating method.

Next, as illustrated in FIG. 4B, for example, a resist pattern PP having a line width of 2 μm is formed on the surface 350a of the sealing member 300. The resist pattern PP is formed to include an opening Op at a position vertically overlapping the electrode 400a exposed to the surface 350a. In the opening Op, the seed layer Sd is exposed. Next, the plating layer EL that covers the seed layer Sd exposed to the opening Op is formed using an electroplating method. The plating layer EL also includes Cu or the like. At this time, a part of the plating layer EL may also be formed on the resist pattern PP.

Next, as illustrated in FIG. 4C, after removing the resist pattern PP using a lift-off method or the like, the seed layer Sd exposed to the portion where the resist pattern PP was removed is removed by etching or the like. As a result, the wiring layer 621 is formed in a region corresponding to the opening Op of the resist pattern PP. The wiring layer 621 includes the seed layer Sd and the plating layer EL. The wiring layer 621 is connected to the electrode 400a in the up-down direction.

Next, as illustrated in FIG. 4D, the insulating layer 610 that covers the wiring layer 621, the via layer V0 that extends in the insulating layer 610 and is electrically connected to the wiring layer 621, the wiring layer 623, the via layer V1, and the wiring layer 622 is formed. As a result, the redistribution layer 600a is formed.

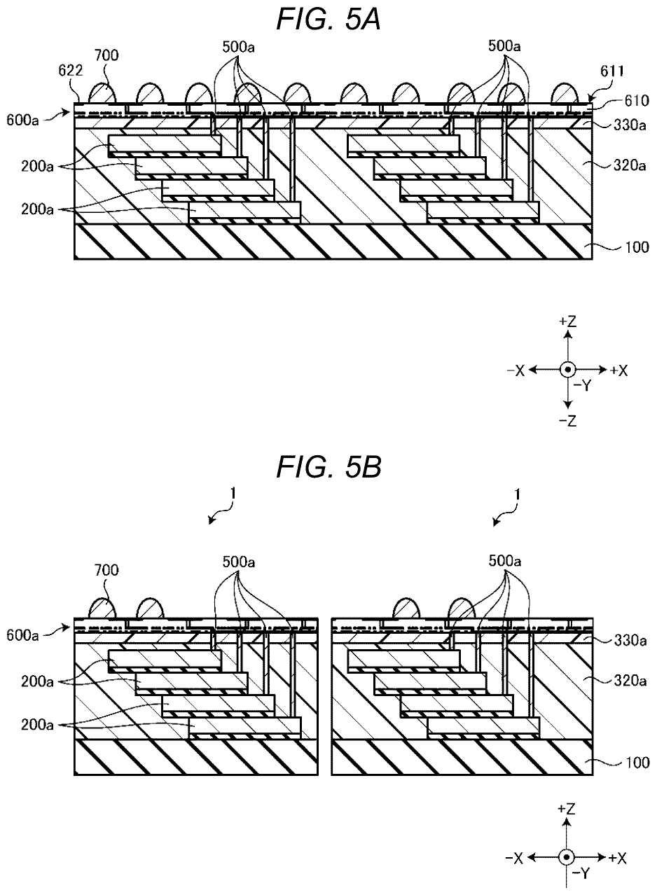

As illustrated in FIG. 5A, the solder balls 700 for connection to the wiring layer 622 are formed on the upper surface 611 of the insulating layer 610. The solder balls 700 are formed, for example, using a thermocompression bonding technique, an ultrasonic bonding technique, or a mass reflow technique of dissolving a solder arranged in an array to form the plurality of solder balls 700 at once.

As illustrated in FIG. 5B, the support 100 is diced into small pieces. As a result, the semiconductor device 1 according to the first embodiment is manufactured.

### Comparative Example

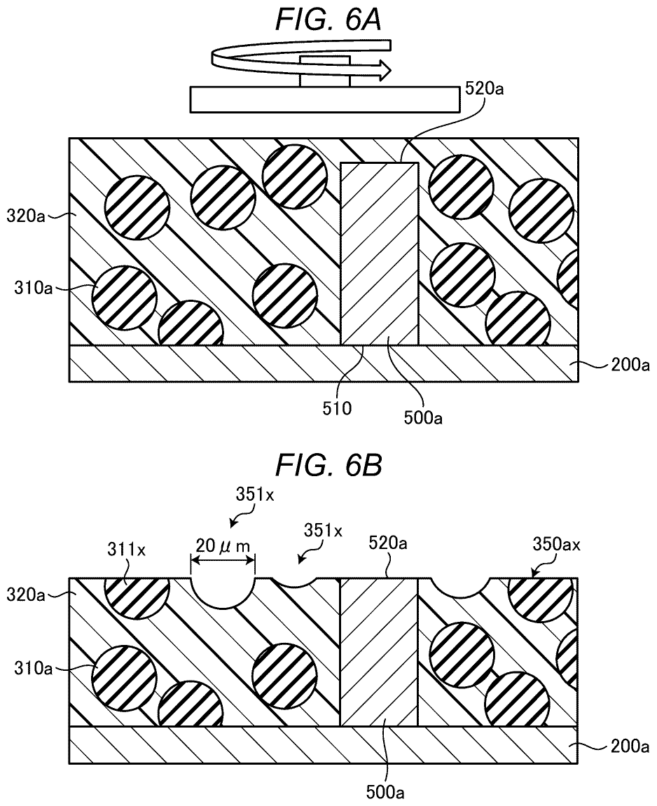

Next, a semiconductor device according to a comparative example will be described using FIGS. 6A and 6B. FIGS. 6A and 6B are cross-sectional views illustrating a part of a procedure of a method of manufacturing a semiconductor device according to this comparative example. More specifically, FIGS. 6A and 6B are enlarged cross-sectional views including the end portion 520a of the vertical wire 500a that correspond in position to FIGS. 3A and 3B.

As illustrated in FIG. 6A, in the method of manufacturing the semiconductor device according to this comparative example, the second layer 330a is not formed. That is, the semiconductor chips 200a and the vertical wires 500a are covered with only the first layer 320a including the fillers 310a.

This first layer 320a is polished a CMP method to expose the end portion 520a of the vertical wire 500a at a surface 350ax.

At this time, the various materials (having different material characteristic and hardnesses) of the first layer 320a, the fillers 310a, the vertical wire 500a, and the like must be polished using a CMP method, which increases the difficulty of the polishing. The reason for this is that, when components having different mechanical strengths are polished under the same conditions, loads are non-uniformly applied to the respective components at the surface being polished and the polishing rate varies depending on the materials being polished.

In addition, as illustrated in FIG. 6B, a portion 311x where a chipped filler 310a (a partial filler 310a or a portion of an original filler 310a) is exposed to the surface 350ax or a cratered recess portion 351x that is a cavity formed after an exposed filler 310a comes out is formed on the surface 350ax. When the filler 310a is present at the same height position as that of the polishing surface of the first layer 320a, the portion 311x is formed by not only the first layer 320a but also a part of the filler 310a. In this process, the recess portion 351x may also be formed as portion 311x comes off from the polishing surface in the polishing process. The maximum diameter of the portion 311x and the recess portion 351x may be substantially the same as the diameter of the original filler 310a.

It is difficult to form a wiring layer for the redistribution layer on a surface 350ax on which a recess portion 351x has formed. When the recess portion 351x is formed on the surface 350ax, the thickness of a resist film applied to the surface 350ax will be non-uniform, and it will be difficult to provide a fine resist pattern (having a line width of about 2 μm) by a conventional exposure method or, alternatively, it may be difficult to uniformly form the plating layer to be used as the wiring layer on the uneven surface 350ax.

In the semiconductor device 1 according to the first embodiment, all of the fillers 310a are present at depth positions lower than the surface 350a. That is, a portion 311x of the filler 310a and a recess portion 351x are not exposed to the surface 350a. As a result, the wiring layer 621 can be easily formed on the surface 350a.

In addition, all of the fillers 310a being present at the depth positions lower than the surface 350a means there are no portions 311x of a filler 310a and no recess portions 351x exposed to the polished surface forming the surface 350a. That is, only two types of components (the first layer 320a and the vertical wire 500a) are exposed to the polishing process. Therefore, the polishing for forming the surface 350a can be relatively easily performed.

### First Modification Example

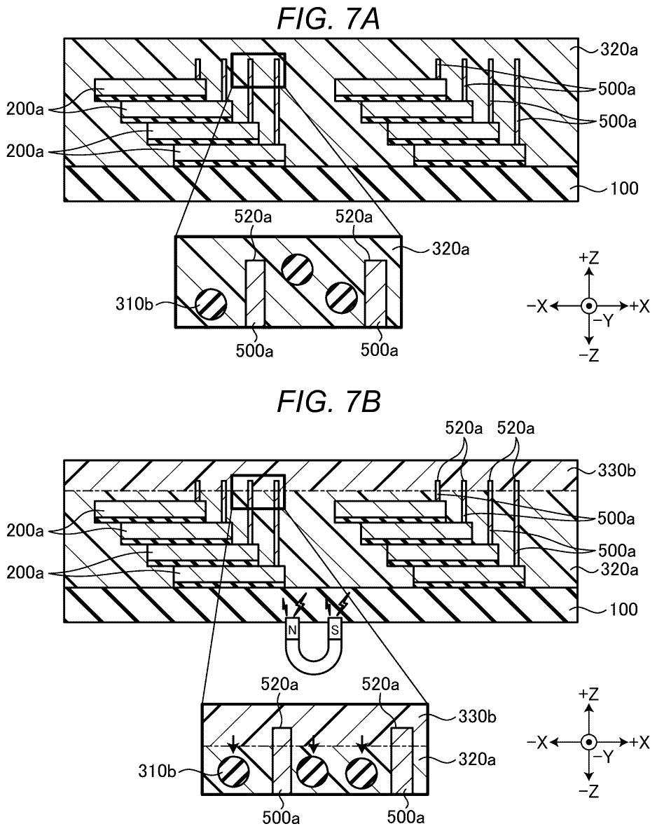

A method of manufacturing a semiconductor device according to a first modification example of the first embodiment will be described using FIGS. 7A and 7B. In the method of manufacturing the semiconductor device according to the first modification example, a method of forming the first layer 320a and a second layer 330b is different from that of the first embodiment.

Hereinafter, the same components as those of the first embodiment will be represented by the same reference symbols, and the description thereof may not be repeated.

FIGS. 7A and 7B are cross-sectional views illustrating a part of a procedure of a method of manufacturing the semiconductor device according to the first modification example of the first embodiment. FIGS. 7A and 7B do not specifically illustrate the mold. In addition, generally, the support 100 should be inverted upside down in illustration. However, in FIGS. 7A and 7B, the support 100 is simply illustrated on the lower side.

Prior to FIG. 7A, the processes up to FIG. 2C of the first embodiment are performed. It should be noted that, in the process corresponding to FIG. 2C, for the first modification example, the first layer 320a including fillers 310b among the filler-containing layer and the filler non-containing layer is disposed on the mold. As a result, as illustrated in FIG. 7A, the semiconductor chips 200a and the vertical wires 500a are covered with the non-cured first layer 320a.

The fillers 310b in the non-cured first layer 320a may comprise, for example, a magnetic material such as nickel or cobalt. The fillers 310b can be moved within the non-cured first layer 320a with an applied magnetic field.

As illustrated in FIG. 7B, the magnetic field is generated on the support 100 side when seen from the non-cured first layer 320a. As a result, the fillers 310b move toward the support 100 side in the first layer 320a.

By moving the fillers 310b toward the support 100 side, a second layer 330b from which the fillers 310b are removed is formed in the upper region of the first layer 320a, that is, the region opposite to the support 100. The second layer 330b can comprise the same resin as the first layer 320a but does not include the fillers 310b therein. The second layer 330b is disposed over the first layer 320a and covers the end portion 520a side of the vertical wire 500a.

After FIG. 7B, the processes of FIGS. 3 to 5 of the first embodiment are performed. As a result, the semiconductor device according to the first modification example is manufactured.

With the method of manufacturing the semiconductor device according to the first modification example, a semiconductor device that exhibits the same effect as that of the semiconductor device 1 according to the first embodiment can be obtained.

### Second Modification Example

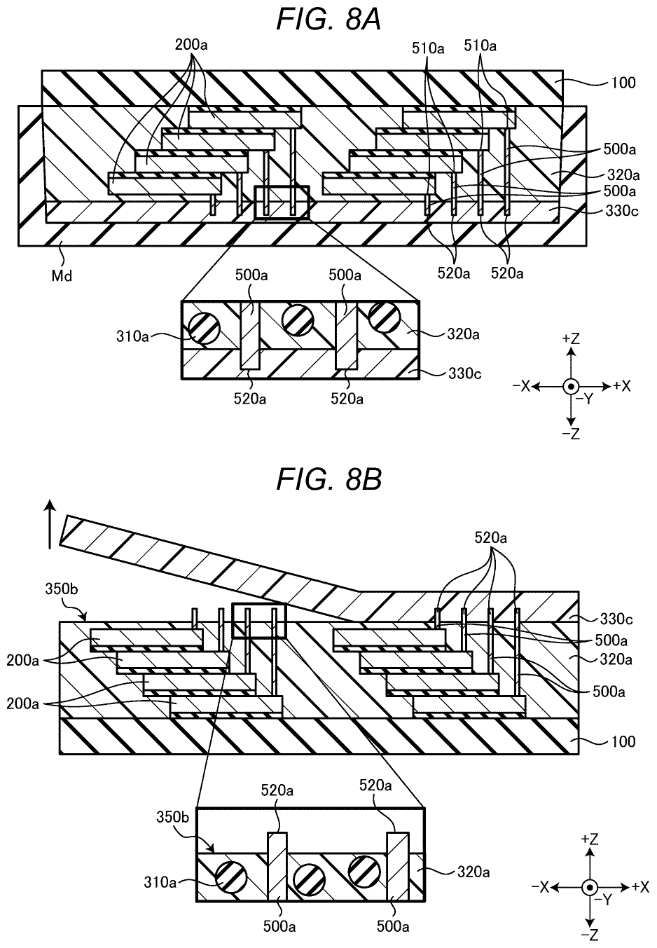

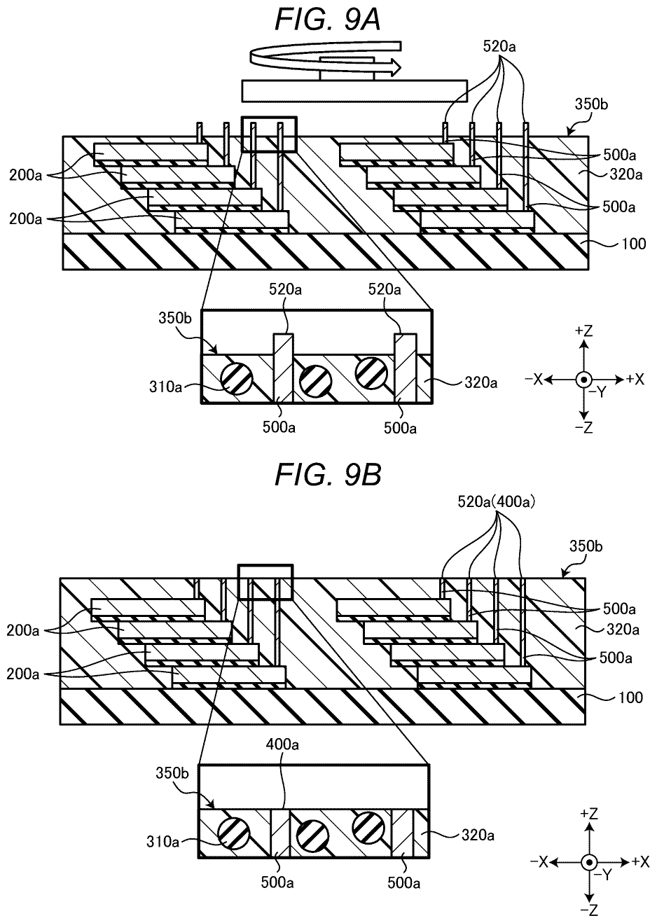

A method of manufacturing a semiconductor device according to a second modification example of the first embodiment will be described using FIGS. 8A to 9B. The method of manufacturing the semiconductor device according to the second modification example is different from the first embodiment in that a mold release film is used as a second layer 330c.

Hereinafter, the same components as those of the first embodiment will be represented by the same reference symbols, and the description thereof may not be repeated.

FIGS. 8A to 9B are cross-sectional views illustrating a part of a procedure of the method of manufacturing the semiconductor device according to the second modification example of the first embodiment.

Prior to FIG. 8A, the processes up to FIG. 2B of the first embodiment are performed.

As illustrated in FIG. 8A, a second layer 330c that is a mold release film is disposed on the bottom portion of the mold Md, and the non-cured first layer 320a is disposed thereon. The first layer 320a and the second layer 330c are a thermosetting resin, such as an epoxy resin or an acrylic resin. The first layer 320a and the second layer 330c can comprise the same resin material or different resin materials.

The non-cured first layer 320a includes a plurality of fillers 310a. The second layer 330c used as a mold release film in this context does not include any fillers 310a.

The support 100 is inverted upside down and the support 100 is inserted into the mold Md up to a depth position where the end portion 520a of the vertical wire 500a reaches the second layer 330c. As a result, the semiconductor chips 200a and the portions on the side of the end portions 510a of the vertical wires 500a are covered with the first layer 320a, and the end portions 520a of the vertical wires 500a protrude into the second layer 330c.

Next, the first layer 320a is cured, and the cured first layer 320a and the second layer 330c are taken out from the mold Md.

Next, as illustrated in FIG. 8B, the second layer 330c is removed by being peeled off from the first layer 320a. By removing the second layer 330c, a surface 350b of the first layer 320a is exposed. The end portions 520a of the vertical wires 500a protrude from the surface 350b. This way, in the second modification example, the first layer 320a having the surface 350b seals the plurality of semiconductor chips 200a. The surface 350b is an example of a first surface.

As illustrated in FIG. 9A, using a CMP method, the portion of the vertical wire 500a protruding from the surface 350b is removed (polished). Specifically, as illustrated in FIG. 9B, the vertical wire 500a is polished such that the height position of the surface 350b is substantially the same as the height position of the end portion 520a of the vertical wire 500a. The end portion 520a of the vertical wire 500a (positioned on the surface 350b of the first layer 320a that is the sealing member 300) functions as the electrode 400a.

After FIG. 9B, the processes of FIGS. 4A to 5B of the first embodiment are performed. As a result, the semiconductor device according to the second modification example is manufactured.

With the method of manufacturing the semiconductor device according to the second modification example, a semiconductor device that exhibits the same effect as that of the semiconductor device 1 according to the first embodiment can be obtained.

### Third Modification Example

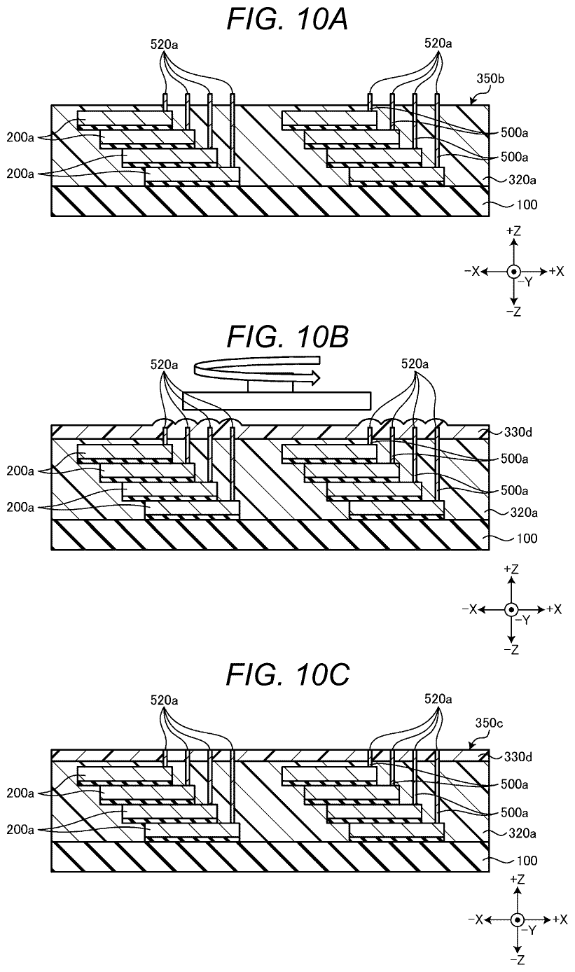

A method of manufacturing a semiconductor device according to a third modification example of the first embodiment will be described using FIGS. 10A to 10C. The method of manufacturing the semiconductor device according to the third modification example is a modification example of the method of manufacturing the semiconductor device according to the second modification example.

Hereinafter, the same components as those of the second modification example will be represented by the same reference symbols, and the description thereof may not be repeated.

FIGS. 10A to 10C are cross-sectional views illustrating a part of a procedure of the method of manufacturing the semiconductor device according to the third modification example of the first embodiment.

Prior to FIG. 10A, even in the method of manufacturing the semiconductor device according to the third modification example, the processes up to FIG. 8B of the above-described second modification example are performed.

As illustrated in FIG. 10A, an upper side portion including the end portion 520a of the vertical wire 500a protrudes from the surface 350b of the first layer 320a.

As illustrated in FIG. 10B, for example, using a spin coating method, a second layer 330d that covers the end portion 520a of the vertical wire 500a is formed on the surface 350b. The second layer 330d is a thermosetting resin, such as an epoxy resin or an acrylic resin. In some examples, the second layer 330d comprises a resin that is the same as or different from that of the first layer 320a. The second layer 330d does not include the fillers 310a.

Next, using a CMP method or the like, the second layer 330d is polished. As a result, as illustrated in FIG. 10C, the height of the second layer 330d is reduced to form a surface 350c, and the end portion 520a of the vertical wire 500a is exposed to the surface 350c. This way, in the third modification example, the first layer 320a and the second layer 330d having the surface 350c seal the plurality of semiconductor chips 200a as the sealing member. The surface 350c is an example of the first surface.

After FIG. 10C, the processes of FIGS. 4A to 5B of the first embodiment are performed. As a result, the semiconductor device according to the third modification example is manufactured.

With the method of manufacturing the semiconductor device according to the third modification example, the end portion 520a of the vertical wire 500a protruding from the first layer 320a is covered with the second layer 330d, and by grinding only the second layer 330d, the height positions of the surface 350c of the second layer 330d and the height position of the end portion 520a of the vertical wire 500a are aligned. As a result, processing is easier as compared to when the vertical wire 500a protruding from the sealing member is polished.

With the method of manufacturing the semiconductor device according to the third modification example, a semiconductor device that exhibits the same effect as that of the semiconductor device 1 according to the first embodiment can be obtained.

### Fourth Modification Example

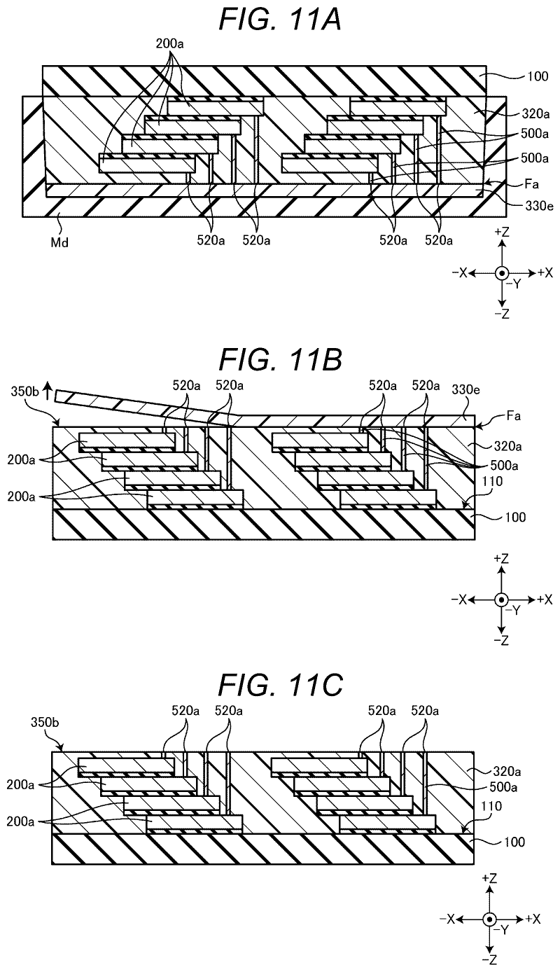

A method of manufacturing a semiconductor device according to a fourth modification example of the first embodiment will be described using FIGS. 11A to 11C. The method of manufacturing the semiconductor device according to the fourth modification example is another modification example of the method of manufacturing the semiconductor device according to the second modification example.

Hereinafter, the same components as those of the second modification example will be represented by the same reference symbols, and the description thereof may not be repeated.

FIGS. 11A to 11C are cross-sectional views illustrating a part of a procedure of the method of manufacturing the semiconductor device according to the fourth modification example of the first embodiment.

Prior to FIG. 11A, the processes up to FIG. 2B of the first embodiment are performed.

As illustrated in FIG. 11A, a second layer 330e is disposed on the bottom portion of the mold Md, and the first layer 320a is disposed thereon. The first layer 320a and the second layer 330e include the same resin or different resins. The second layer 330e is configured as a mold release film as in the second layer 330c according to the second modification example. As the second layer 330e, the same mold release film as the second layer 330c according to the second modification example may also be used.

The support 100 is inverted upside down and the support 100 is inserted into the mold Md up to a depth position where the end portion 520a of the vertical wire 500a reaches an interface Fa between the second layer 330e and the first layer 320a. At this time, the end portion 520a of the vertical wire 500a is positioned in the interface Fa between the second layer 330e and the first layer 320a, and is not inserted into the second layer 330e. In order to allow the end portion 520a of the vertical wire 500a to abut against the interface Fa between the second layer 330e and the first layer 320a and not to be inserted into the second layer 330e, various methods are possible.

For example, a method of controlling the thicknesses of the second layer 330e and the first layer 320a to be filled in the mold Md to precisely set the position of the interface Fa between the second layer 330e and the first layer 320a in the mold Md is considered. In addition, as the second layer 330e, a mold release film that is harder than the second layer 330c according to the second modification example may be adopted. In some examples, the end portion 520a of the vertical wire 500a may be polished beforehand to make the end portion 520a blunt or the like. The reason for this is that, when the vertical wire 500a has the sharp end portion 520a, the vertical wire 500a may break through the interface Fa between the second layer 330e and the first layer 320a and is thus to be likely to be inserted into the second layer 330e.

Next, the first layer 320a is cured, and the cured first layer 320a and the second layer 330e are taken out from the mold Md.

As illustrated in FIG. 11B, all of the semiconductor chips 200a including the vertical wires 500a are covered with the first layer 320a. The second layer 330e covers the upper side of the first layer 320a. In addition, as described above, the end portion 520a of the vertical wire 500a extends in the first layer 320a, and reaches a height position that is substantially the same as that of the interface Fa.

Next, the second layer 330e is peeled off from the first layer 320a. By peeling off the second layer 330e, the surface 350b of the first layer 320a is exposed. As illustrated in FIG. 11C, the end portion 520a of the vertical wire 500a is exposed to the surface 350b of the first layer 320a.

After FIG. 11C, each of the processes of FIGS. 4A to 5B of the first embodiment is performed. As a result, the semiconductor device according to the fourth modification example is manufactured.

With the method of manufacturing the semiconductor device according to the fourth modification example, the semiconductor chips 200a are sealed such that the end portion 520a of the vertical wire 500a is positioned in the interface Fa between the second layer 330e and the first layer 320a. As a result, after sealing the plurality of semiconductor chips 200a, the grinding of the sealing member does not need to be performed, and the number of steps can be reduced, which can reduce the manufacturing cost of the semiconductor device.

With the method of manufacturing the semiconductor device according to the fourth modification example, a semiconductor device that exhibits the same effect as that of the semiconductor device 1 according to the first embodiment can be obtained.

### Second Embodiment

The sealing members 300 having the configurations of the first embodiment and the first to fourth modification examples described above are also applicable to various semiconductor devices having a different configuration from the above-described semiconductor device 1 or the like.

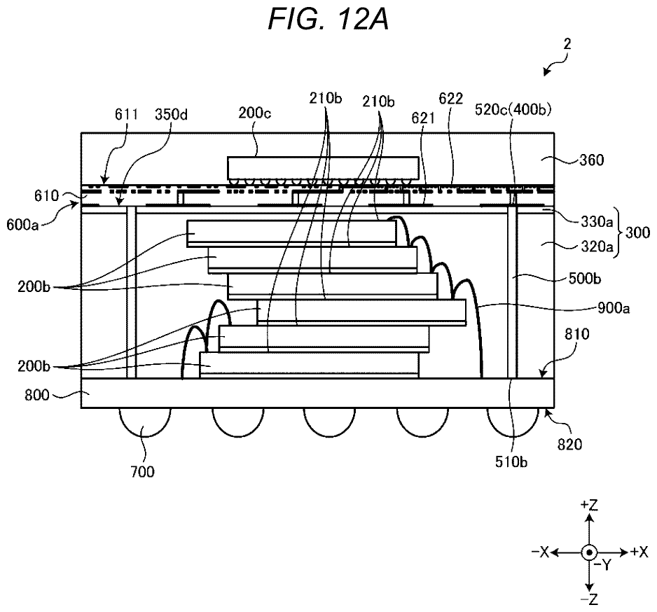

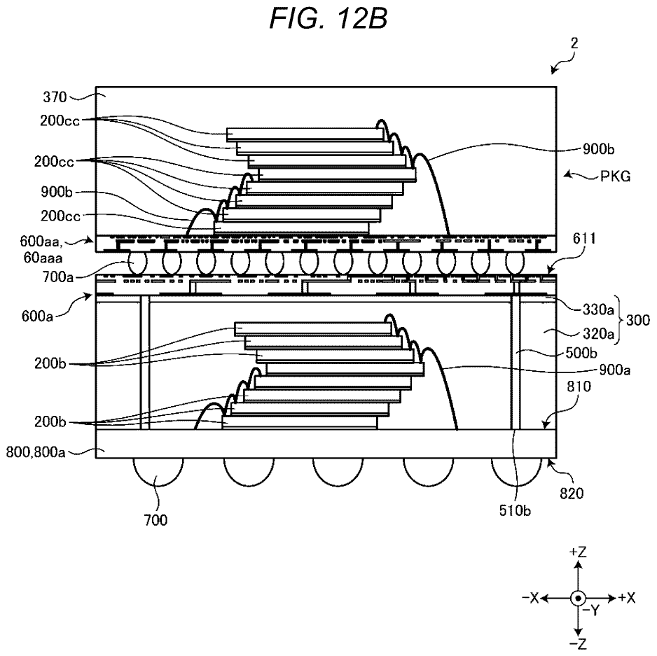

In the following second embodiment, as an application example of the sealing member 300 having the configuration of the first embodiment, a semiconductor device having a package-on-package structure will be described using FIG. 12A.

Hereinafter, the same components as those of the first embodiment will be represented by the same reference symbols, and the description thereof may not be repeated.

### Configuration Example of Semiconductor Device

FIG. 12A is a diagram illustrating an example of a configuration of a semiconductor device 2 according to the second embodiment. FIG. 12A illustrates a cross-section taken along the X direction of the semiconductor device 2. It should be noted that FIG. 12A does not include hatching in consideration of easier understanding of the drawing.

As illustrated in FIG. 12A, the semiconductor device 2 includes a plurality of semiconductor chips 200b, a semiconductor chip 200c, sealing members 300 and 360, an electrode 400b, a vertical wire 500b, the redistribution layer 600a, the solder ball 700, a wiring substrate 800, and a wire 900a.

The wiring substrate 800 can be a multilayer board in which an insulating layer and a conductive layer are alternately stacked multiple times. The insulating layer is formed of, for example, carbon fibers, glass fibers or aramid fibers impregnated with a thermosetting resin such as an epoxy resin before curing. The conductive layer is formed of, for example, a metal such as Cu. The conductive layer has a wiring pattern and is connected to an electrode formed on an upper surface 810 and a lower surface 820 of the wiring substrate 800.

The plurality of semiconductor chips 200b are stacked on the upper surface 810 of the wiring substrate 800. Each of the plurality of semiconductor chips 200b includes, for example, a semiconductor element on a main surface 210b side. The semiconductor element may be a plurality of memory cells. That is, each of the plurality of semiconductor chips 200b can be a memory chip such as a NAND flash memory. The semiconductor chip 200b is an example of a first semiconductor chip.

The plurality of semiconductor chips 200b are stacked while being shifted in the positive X direction or the negative X direction toward the upper side. For example, as illustrated in FIG. 12A, among the plurality of semiconductor chips 200b, at least some semiconductor chips 200b, for example, the semiconductor chips 200b on the lower layer side are stacked to be shifted in the positive X direction.

In addition, for the semiconductor chips 200b on the upper layer side among the plurality of semiconductor chips 200b, the shift direction is inverted from that of the semiconductor chips 200b on the lower layer side, and the semiconductor chips 200b on the upper layer side may be stacked to be shifted in the negative X direction. This way, when the number of the semiconductor chips 200b to be stacked is large, the shift direction in the X direction when the plurality of semiconductor chips 200b are stacked may be switched.

As a result, in an end portion of the main surface 210b of each of the semiconductor chips 200b on the side of positive X direction or the side of negative X direction, a portion not overlapping the semiconductor chip 200b immediately thereabove is present. In this portion and an end portion of the main surface 210b of the semiconductor chip 200b at the uppermost layer on the side of the positive X direction or the negative X direction, an electrode pad is provided. The wire 900a is connected to this electrode pad.

The wire 900a comprises, for example, a metal material such as Au, Cu, Pd, or Ag or alloys thereof. The wire 900a connects the semiconductor chips 200b to an electrode provided on the upper surface 810 of the wiring substrate 800 to each other. As a result, the wiring substrate 800 and the plurality of semiconductor chips 200b are electrically connected.

The sealing member 300 covers the plurality of semiconductor chips 200b. In at least a part of the sealing member 300, a plurality of fillers 310a are unevenly distributed.

More specifically, as in the first embodiment, the sealing member 300 includes a first layer 320a including fillers and a second layer 330a not including fillers. The first layer 320a covers a lower portion including the upper surface 810 of the wiring substrate 800, the semiconductor chips 200b, the wire 900a, and an end portion 510b that is a connection end of the vertical wire 500b to the wiring substrate 800. The second layer 330a is disposed on above the first layer 320a and covers an upper portion of the vertical wire 500a including an end portion 520c of the vertical wire 500a.

The electrode 400b is exposed to a surface 350d of the second layer 330a. The electrode 400b is also the end portion 520c of the vertical wire 500b.

The vertical wire 500b is connected to an electrode provided on the upper surface 810 of the wiring substrate 800 in the end portion 510b. The vertical wire extends upward in the first layer 320a and the second layer 330a and is exposed to the surface 350d in the end portion 520c that is the second end portion. As a result, the plurality of semiconductor chips 200b are electrically led out to the surface 350d through the wire 900a, the wiring substrate 800 and the vertical wire 500b. The vertical wire 500b is an example of a first conductive structure. For example, the vertical wire 500b is a columnar type structure.

The redistribution layer 600a is formed on the surface 350d. As in the first embodiment, the redistribution layer 600a is connected to the electrode 400b, and includes the wiring layer 621 extending on the surface 350d.

The semiconductor chip 200c is provided on the upper surface 611 of the insulating layer 610 of the redistribution layer 600a. The semiconductor chip 200c is configured as a controller chip that controls the NAND flash memory and the like in the plurality of semiconductor chips 200b. It should be noted that, although not limited thereto, the semiconductor chip 200c may be a logic chip such as an application processor.

The semiconductor chip 200c is electrically connected to the plurality of semiconductor chips 200b through the redistribution layer 600a. The semiconductor chip 200c is sealed with a sealing member 360. The semiconductor chip 200c is an example of the second semiconductor chip.

The plurality of solder balls 700 are provided on the lower surface 820 of the wiring substrate 800. The plurality of solder balls 700 are connected to an electrode formed on the lower surface 820 of the wiring substrate 800. As a result, the plurality of semiconductor chips 200b and the semiconductor chip 200c are electrically connected to the solder balls 700.

The semiconductor device 2 according to the second embodiment may include a redistribution substrate 800a instead of the wiring substrate 800. For example, when the redistribution substrate 800a is used, the redistribution layer is formed on the supporting substrate, the plurality of semiconductor chips 200b are stacked on the redistribution layer, and subsequently the wire 900a for connection to each of the semiconductor chips 200b is formed. In one manufacturing method, after sealing the plurality of semiconductor chips 200b and the wire 900a with the sealing member 300, the redistribution layer 600a is formed on the sealing member 300, the supporting substrate is peeled off, and the redistribution substrate 800a is exposed. Of course, the wiring substrate 800 may also be used as in FIG. 12A.

In addition, as illustrated in FIG. 12B, in the semiconductor device 2 according to the second embodiment, a package PKG where a plurality of semiconductor chips 200cc are sealed instead of the semiconductor chips 200c may be provided on the upper surface of the redistribution layer 600a.

FIG. 12B is a diagram illustrating another example of the configuration of the semiconductor device 2 according to the second embodiment. FIG. 12B illustrates a cross-section taken along the X direction of the semiconductor device 2. It should be noted that FIG. 12B does not include hatching in consideration of easier understanding of the drawing.

As described above, the package PKG is provided on the upper surface 611 of the redistribution layer 600a. The package PKG has a configuration where the plurality of semiconductor chips 200cc are sealed with a sealing member 370 on a redistribution layer 600aa. The plurality of semiconductor chips 200cc and the redistribution layer 600aa are connected through a wire 900b.

A plurality of solder balls 700a are provided on a lower surface of the redistribution layer 600aa. The plurality of solder balls 700a are connected to a wiring layer extending on the upper surface 611 of the redistribution layer 600a. As a result, a plurality of semiconductor chips 200d and the solder balls 700 are electrically connected through the solder balls 700a.

In the method of manufacturing the semiconductor device 2 of FIG. 12B, after individually forming the packages PKG, the package PKG and the redistribution layer 600a are connected through the plurality of solder balls 700a.

In addition, the semiconductor device 2 of FIG. 12B may include a wiring substrate 60aaa instead of the redistribution layer 600aa. In the upper package PKG of the semiconductor device 2 of FIG. 12B, the semiconductor chips 200c of FIG. 12A may be provided instead of the plurality of semiconductor chips 200cc. FIGS. 12A and 12B illustrate examples of the semiconductor device 2. The semiconductor chips 200c may be provided on the lower package, and the plurality of semiconductor chips 200cc may be provided on the upper package PKG. Alternatively, in both of the lower package and the upper package PKG, a logic chip such as an application processor may be provided.

In the semiconductor device 2 according to the second embodiment, the same effects as those of the semiconductor device 1 according to the first embodiment are exhibited.

### Third Embodiment

The sealing members 300 having the configurations of the first embodiment and the first to fourth modification examples are also applicable to a semiconductor device including a three-dimensional nonvolatile memory or the like where a plurality of memory cells are three-dimensionally arranged.

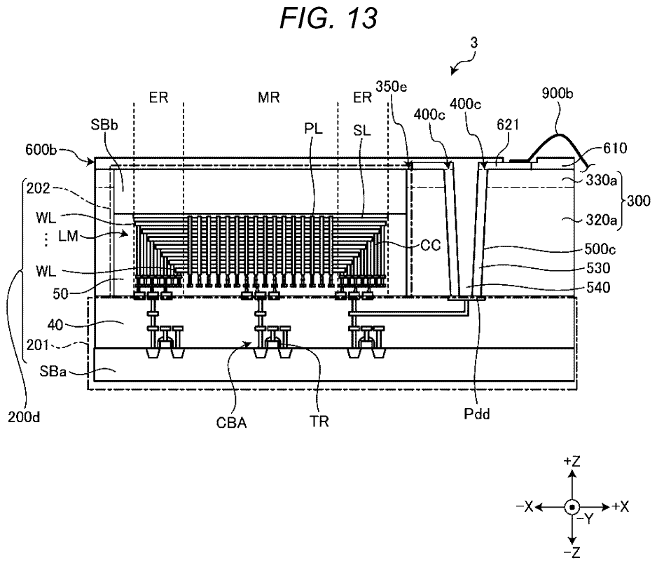

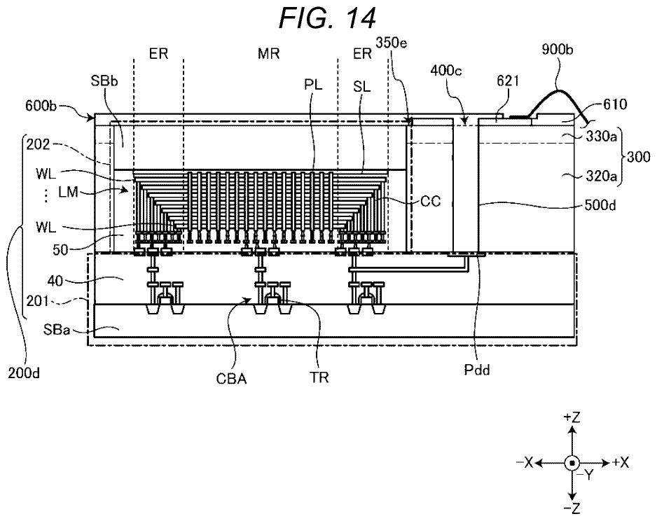

In the following third embodiment, as an application example of the sealing member 300 having the configuration of the first embodiment, a semiconductor device including a three-dimensional nonvolatile memory will be described using FIGS. 13 and 14.

Hereinafter, the same components as those of the first embodiment will be represented by the same reference symbols, and the description thereof may not be repeated.

### Configuration Example of Semiconductor Device

FIG. 13 is a diagram illustrating an example of a configuration of a semiconductor device 3 according to the third embodiment. FIG. 13 illustrates a cross-section taken along the X direction of the semiconductor device 3. It should be noted that FIG. 13 does not include hatching in consideration of easier understanding of the drawing.

As illustrated in FIG. 13, the semiconductor device 3 includes the semiconductor chip 200d, the sealing member 300, an electrode 400c, a through-hole contact 500c, and a redistribution layer 600b.

The semiconductor chip 200d includes a CMOS-side chip 201 and an array-side chip 202 that is bonded to an upper surface of the CMOS-side chip 201. The CMOS-side chip 201 and the array-side chip 202 may be bonded after being individually formed and cut.

The CMOS-side chip 201 includes a peripheral circuit CBA provided on a substrate SBa. The array-side chip 202 includes a stacked body LM where a plurality of word lines WL are stacked and a source line SL in this order from below. The semiconductor chip 200d is an example of the first semiconductor chip.

The substrate SBa is, for example, a silicon (Si) substrate. The peripheral circuit CBA including a transistor TR, a wiring, and the like is disposed on the substrate SBa. The peripheral circuit CBA contributes to an operation of the memory cell.

The peripheral circuit CBA is covered with an insulating layer 40 such as a silicon oxide layer. The array-side chip 202 is disposed on a part of an upper surface of the insulating layer 40. That is, the chip area of the array-side chip 202 is less than the chip area of the CMOS-side chip 201.

The stacked body LM of the array-side chip 202 has a configuration where the plurality of word lines WL are stacked apart from each other. A memory region MR is disposed in a center portion of the stacked body LM, and a stepwise region ER is disposed in both end portions of the stacked body LM. The word line WL is an example of the conductive layer.

In the memory region MR, a plurality of pillars PL that penetrate the word lines WL in the stacking direction are disposed. An upper end of the pillar PL reaches the source line SL. A plurality of memory cells are formed at intersections between the pillars PL and the word lines WL. This way, the semiconductor chip 200d is configured as a three-dimensional nonvolatile memory where the memory cells are three-dimensionally disposed in the memory region MR.

A plurality of contacts CC that are respectively connected to the plurality of word lines WL are disposed in the stepwise region ER. That is, a write voltage, a read voltage, and the like are applied from the contacts CC to the memory cells in the memory region MR of the center portion of the stacked body LM through the word lines WL at the same height positions as the memory cells. Various voltages applied from the contacts CC to the memory cells are controlled by the peripheral circuit CBA that is electrically connected to the contacts CC.

The plurality of word lines WL, the pillars PL, and the contacts CC are covered with an insulating layer 50 such as silicon oxide. A substrate SBb is disposed over the insulating layer 50. The substrate SBb is, for example, a silicon (Si) substrate. With the above-described configuration, the semiconductor chip 200d is formed.

The sealing member 300 seals the semiconductor chip 200d. Specifically, the sealing member 300 covers the upper surface of the CMOS-side chip 201 and a peripheral portion of the array-side chip 202.

More specifically, the sealing member 300 has a two-layer structure including the first layer 320a including the plurality of fillers and the second layer 330a not including the fillers. The first layer 320a covers a portion of the upper surface of the CMOS-side chip 201 where the array-side chip 202 is not disposed, a lower portion of the array-side chip 202, and a lower portion of the through-hole contact 500c. The second layer 330a is disposed above the first layer 320a and covers an upper portion of the through-hole contact 500c.

The electrode 400c is exposed to a surface 350e of the second layer 330a. The electrode 400c is a first end portion of a conductive layer 530 of the through-hole contact 500c. The surface 350e is an example of the first surface.

In the through-hole contact 500c, the conductive layer 530 and an insulating layer 540 are formed in this order from the outside. The conductive layer 530 and the insulating layer 540 of the through-hole contact 500c are connected to an electrode pad Pdd exposed to the upper surface of the CMOS-side chip 201 in the lower end portion, extend upward in the first layer 320a and the second layer 330a, and are exposed to the surface 350e in the second end portion. The electrode pad Pdd is connected to the peripheral circuit CBA of the CMOS-side chip 201. As a result, the semiconductor chip 200d is electrically led out to the surface 350e through the through-hole contact 500c. The conductive layer 530 is an example of the first conductive structure.

The redistribution layer 600b is formed on the surface 350e. As in the first embodiment, the redistribution layer 600b is connected to the electrode 400c and includes the wiring layer 621 extending on the surface 350e.

The wire 900b is connected to an upper surface of the wiring layer 621. The wire 900b comprises, for example, a metal material such as Au, Cu, Pd, or Ag or alloys thereof. The wire 900b is formed using, for example, a wire bonding method. The wire 900b connects the wiring layer 621 and a wiring layer of another semiconductor device to each other. As a result, the semiconductor device 3 is electrically connected to the other semiconductor device.

As illustrated in FIG. 14, the semiconductor device 3 according to the third embodiment may include a vertical wire 500d instead of the above-described through-hole contact 500c. Alternatively, a copper (Cu) pillar may be provided instead of the through-hole contact 500c. A Cu pillar that is connected to the electrode pad Pdd can be formed before sealing the semiconductor chip 200d with the sealing member 300. After sealing the semiconductor chip 200d with the sealing member 300, the Cu pillar exposed at the surface 350e is ground (polished) using a CMP method. As a result, the electrode 400c is formed on the surface 350e.

As illustrated in FIG. 14, the vertical wire 500d vertically extends in the second layer 330a and the first layer 320a and connects the wiring layer 621 and the electrode pad Pdd exposed to the upper surface of the CMOS-side chip 201 to each other.

As described above, by applying the sealing member 300 according to any one of the first embodiment and the first to fourth modification examples to a semiconductor device including a three-dimensional nonvolatile memory, in the sealing member 300 removed from the semiconductor chip 200d, the through-hole contact 500c, the vertical wire 500d, or the like is formed, and the redistribution thereof can be easily performed on the upper surface of the sealing member 300.

### Comparative Example

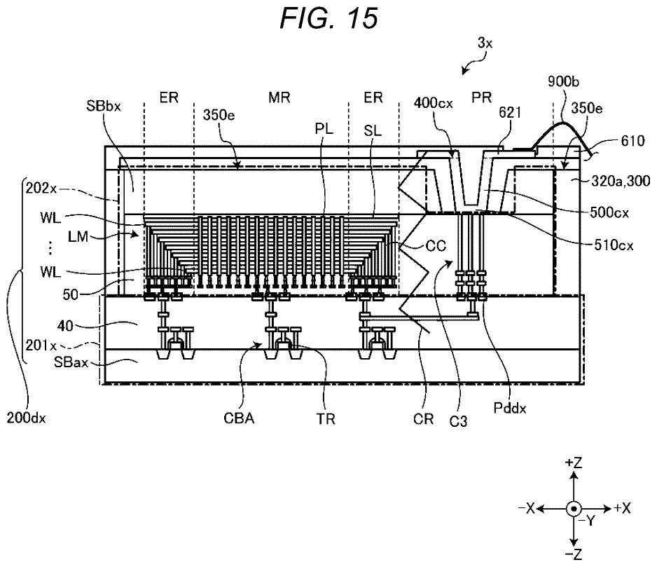

Next, a semiconductor device according to a comparative example will be described using FIG. 15. FIG. 15 is a diagram of a semiconductor device 3x according to a comparative example. It should be noted that FIG. 15 does not include hatching in consideration of easier understanding of the drawing.

In this comparative example, when the semiconductor device is sealed, the described configurational aspects of the first embodiment or the first to fourth modification examples are not adopted. In particular, a through-hole contact and the like are disposed in the sealing member, and the redistribution thereof on the upper surface of the sealing member is thus difficult. Therefore, in the semiconductor device according to the comparative example, a through-hole contact and the like are disposed in a semiconductor chip.

As a result, in the semiconductor device 3x as illustrated in FIG. 15, the chip area of an array-side chip 202x is more extended than that of the semiconductor chips 200d according to the third embodiment, for example. That is, in the array-side chip 202x of a semiconductor chip 200dx according to the comparative example, the areas of the insulating layer 50 and a substrate SBbx additionally extend in the X and Y directions, and an alternate configuration from that of the through-hole contact 500c according to the third embodiment is disposed in the extended portion.

More specifically, a peripheral region PR is disposed on the extended portion of the insulating layer 50, that is, the outside of the stepwise region ER. A conductive layer C3 vertically extending in the insulating layer 50 is formed in the peripheral region PR. The conductive layer C3 is connected to an electrode pad Pddx exposed to an upper surface of a CMOS-side chip 201x in the lower end portion. The electrode pad Pddx is connected to the peripheral circuit CBA. The sealing member 300 covers the outside of the array-side chip 202x providing the extended chip area. In addition, a polyimide layer PI is provided on the surface 350e of the sealing member 300.

An electrode 400cx is exposed at an upper surface of the polyimide layer PI. The electrode 400b is a first end portion of a contact 500cx. The contact 500cx is connected to an upper end portion of the conductive layer C3, extends upward in the extended portion of the substrate SBbx, and is exposed at the upper surface of the polyimide layer PI. That is, the electrode 400cx is disposed over the extended portion of the substrate SBbx.

The wiring layer 621 (that is a part of the redistribution layer) is connected to the electrode 400cx. The wire 900b is connected to the upper surface of the wiring layer 621.

A wire bonding method is used for forming the wire 900b. In the wire bonding method, a first end portion of the wire 900b is compressed on the wiring layer 621. In this process, a downward force is applied to the wiring layer 621 and the electrode 400cx. As a result, a crack CR in the up-down direction near a boundary between the stepwise region ER and the peripheral region PR may be formed.

The insulating layers 40 and 50 are typically silicon oxide layers or the like, and substrates Sbax and SBbx are Si substrates or the like. The silicon oxide layer and the Si substrate have a relatively low elastic modulus. Therefore, when a force is locally applied, the crack CR is likely to be formed.

On the other hand, in the semiconductor device 3 according to the third embodiment, the periphery of the through-hole contact 500c and the electrode 400c is covered with the sealing member 300 (the first layer 320a and the second layer 330a) having a relatively high elastic coefficient (refer to FIG. 13). Therefore, even when a force to direct the wiring layer 621 and the electrode 400c downward is applied, the crack CR is not likely to be formed.

In addition, in the semiconductor device 3 according to the third embodiment, the through-hole contact 500c is disposed in the sealing member 300. Accordingly, the chip area of the array-side chip 202 can be reduced. As a result, a larger number of array-side chips 202 can be cut/diced from the same substrate/wafer, and thus the production cost can be reduced.

In the semiconductor device 3 according to the third embodiment, the same effects as those of the semiconductor device 1 according to the first embodiment are exhibited.

While certain embodiments have been described, these embodiments have been presented by way of example only, and are not intended to limit the scope of the disclosure. Indeed, the novel embodiments described herein may be embodied in a variety of other forms; furthermore, various omissions, substitutions and changes in the form of the embodiments described herein may be made without departing from the spirit of the disclosure. The accompanying claims and their equivalents are intended to cover such forms or modifications as would fall within the scope and spirit of the disclosure.

What is claimed is:

1. A semiconductor device, comprising:
a first semiconductor chip on a substrate;
a sealing member covering the first semiconductor chip, the sealing member including a plurality of fillers and having a first surface, the first semiconductor chip being between the first surface and the substrate;
a first conductive structure having a first end portion electrically connected to the first semiconductor chip, the first conductive structure extending to the first surface through the sealing member and having a second end portion at the first surface; and
a second conductive structure connected to the second end portion and extending along the first surface, wherein
the plurality of fillers is only present in the sealing member at a depth position below the first surface.

2. The semiconductor device according to claim 1, wherein the sealing member comprises:
a first layer in which the plurality of fillers is present, and
a second layer between the first layer and the first surface.

3. The semiconductor device according to claim 2, wherein the first layer and the second layer comprise the same resin material.

4. The semiconductor device according to claim 1, wherein the first conductive structure is a columnar structure.

5. The semiconductor device according to claim 1, wherein the second conductive structure is a wiring layer.

6. The semiconductor device according to claim 1, wherein the fillers of the plurality of fillers are a metal oxide.

7. The semiconductor device according to claim 1, wherein the first end portion of the first conductive structure contacts an end region portion of the first semiconductor chip.

8. The semiconductor device according to claim 1, wherein
the substrate is a wiring substrate, and
the first end portion of the first conductive structure contacts the substrate.

9. The semiconductor device according to claim 1, further comprising:
a second semiconductor chip outside the sealing member and electrically connected to the second conductive layer.

10. The semiconductor device according to claim 9, wherein
the first semiconductor chip is a memory chip which includes a plurality of memory cells, and
the second semiconductor chip is a controller chip configured to perform an electrical operation on the plurality of memory cells.

11. The semiconductor device according to claim 1, wherein the first semiconductor chip includes:
a stacked body in which a plurality of conductive layers are stacked, and
a pillar extending in the stacked body in a layer stacking direction of the stacked body, and
memory cells are formed at each of intersections of the pillar with the plurality of conductive layers.

12. The semiconductor device according to claim 1, further comprising:
a plurality of first semiconductor chips stacked one upon the other, each first semiconductor chip being between the first surface and the substrate.

13. The semiconductor device according to claim 12, further comprising:
a plurality of first conductive structures each having a first end portion electrically connected to one of the plurality of first semiconductor chips and extending from the respective first semiconductor chip to the first surface through the sealing member.

14. A semiconductor device, comprising:
a plurality of first semiconductor chips stacked on a substrate in a first direction;
a sealing member covering the plurality of first semiconductor chips, the sealing member including a plurality of fillers and having a first surface, the plurality of first semiconductor chips being between the first surface and the substrate;
a first conductive structure having a first end portion contacting one of the first semiconductor chips in the plurality of first semiconductor chips, the first conductive structure extending from the one of the first semiconductor chips to the first surface through the sealing member and having a second end portion at the first surface; and
a second conductive structure connected to the second end portion and extending along the first surface, wherein
the plurality of fillers is only present in the sealing member at a depth position below the first surface.

15. The semiconductor device according to claim 14, wherein
the sealing member comprises:
a first layer contacting the substrate and surrounding the plurality of first semiconductor chips, and
a second layer between the first layer and the first surface, and
the plurality of fillers is only in the first layer.

16. The semiconductor device according to claim 15, wherein the first layer and the second layer are a same resin material.

17. A method of manufacturing a semiconductor device, the method comprising:
stacking a plurality of first semiconductor chips on a substrate;
forming a first conductive structure having a first end portion electrically connected to one of the first semiconductor chips in the plurality of first semiconductor chips, the first conductive structure extending in a stacking direction of the plurality of semiconductor chips;
covering the plurality of first semiconductor chips and the first conductive structure with a resin material including a plurality of fillers in at least a part of the resin material;
removing a portion of the resin material to reduce a height of the resin material covering the plurality of first semiconductor chips and a portion of the first conductive structure to expose a second end portion of the first conductive structure at an upper surface of the resin material after the removing of the portion of the resin material to reduce the height of the resin material; and
forming a second conductive structure on the upper surface of the resin material, the second conductive structure contacting the second end portion of the first conductive structure and extending along the upper surface, wherein
the formation of the resin material includes:
covering the plurality of semiconductor chips and the first conductive layer with a first layer including the plurality of fillers therein, and
forming a second layer above the first layer; and
the removing of the portion of the resin material includes:
removing at least a part of the second layer.

18. The method according to claim 17, wherein
the plurality of fillers comprise a magnetic material, and
the forming of the second layer above the first layer includes:
generating a magnetic field to move the plurality of fillers in the resin material away from the first surface of the resin material.

19. The method of manufacturing a semiconductor device according to claim 17, wherein the formation of the resin material further includes:
placing the second layer and the first layer in contact with each other in a mold, and
placing the plurality of first semiconductor chips and the first conductive layer in the mold such that the plurality of first semiconductor chips is positioned between the second layer and the substrate before molding.

20. The method according to claim 17, wherein
the second layer is formed as a film, and
the removing of at least the part of the second layer includes peeling the second layer away from the first layer.
